(19) United States
(12) Patent Application Publication
(10) Pub. No.: US 2026/0316609 A1
(43) Pub. Date: Oct. 15, 2026

(54) INDUCTIVE CHARGING DEVICE AND TESTING METHOD

(71) Applicant: MAHLE International GmbH, Stuttgart (DE)

(72) Inventors: Timo Laemmle, Kernen (DE); Siyuan Lu, Stuttgart (DE); Holger Schroth, Maulbronn (DE)

(21) Appl. No.: 19/465,694

(22) Filed: Jan. 30, 2026

(30) Foreign Application Priority Data
Jan. 31, 2025 (DE) 102025103549.0

(51) Int. Cl. B60L 53/39; B60L 53/12; H02J 50/10; H02J 50/40; H02J 50/80; H02J 50/90

(52) U.S. Cl. CPC B60L 53/39; B60L 53/12; H02J 50/10; H02J 50/402; H02J 50/80; H02J 50/90

(57) ABSTRACT

An inductive charging device may include an energy coil, a positioning mechanism, and a testing unit. The energy coil may be configured to provide an alternating magnetic field for inductive energy transmission to and/or from a second energy coil of a second inductive charging device. The positioning mechanism may include positioning coils for detecting a relative positioning of the energy coils via providing positioning magnetic fields and/or detecting second positioning magnetic fields provided by second positioning coils of the second inductive charging device. The testing unit configured to test an integrity of the positioning coils via excitation of at least one positioning coil and/or the energy coil with a test signal and evaluation of i) a measurement signal induced in a non-excited positioning coil and/or the energy coil and/or ii) a phase shift between current and voltage in the excited positioning coil and/or in a non-excited positioning coil.

### CROSS-REFFERENCE TO RELATED APPLICATION

This application claims priority to German Patent Application No. DE 102025103549.0 filed on Jan. 31, 2025, the contents of which is hereby incorporated by reference in its entirety.

### TECHNICAL FIELD

The invention relates to an inductive charging device and a method for testing the integrity of positioning coils of the inductive charging device. Furthermore, the present invention relates to a vehicle.

### BACKGROUND

An inductive charging system with inductive charging devices for charging an electric vehicle is described in the SAE J 2954:2024-08-13 standard. The Differential Inductive Positioning System (DIPS) is proposed as the standardized positioning system in this standard (Chapter 12; Annexes C and D). This has a position transmitting device (generally also referred to as a positioning device) on the transmitting side, which is arranged in a stationary (first) inductive charging device (also referred to as a ground unit or ground assembly or GA), preferably arranged in or on the ground. This transmitting-side position transmitting device has five transmitting coils (also commonly referred to as positioning coils) in accordance with the standard, each of which generates a positioning magnetic field as an alternating magnetic field with a different frequency. Each transmitting coil is thus driven by an alternating current, with each alternating current having a specific carrier frequency. Such charging devices or parts thereof are also known from DE 102022203489 A1, DE 102022120691 A1, and DE 102022107568 A1.

On the receiving side, a position receiving device (generally also referred to as a positioning device) is provided, which is arranged in a mobile (second) inductive charging device (also referred to as a vehicle unit or vehicle assembly or VA) preferably arranged in or on the underbody of a vehicle. In the example given in the standard, this receiving-side positioning receiving device has two receiving coils (also commonly referred to as positioning coils) that detect the positioning magnetic fields generated by the transmitting coils, which can be distinguished based on their different frequencies. This information can then be used to determine the relative positioning of the inductive charging devices in relation to each other and thus ultimately the positioning of the vehicle relative to the ground-based inductive charging device.

In alternative designs of inductive charging devices, a different number of transmitting and/or receiving coils may also be used. In principle, it is sufficient, for example, if the transmitting-side position transmitting device has at least one transmitting coil and the receiving-side position receiving device has at least one receiving coil.

### SUMMARY

The present invention is based on the task of ensuring correct positioning over the service life of the positioning coils or inductive charging devices.

According to one aspect of the present invention, an inductive charging device is provided, comprising:
an energy coil for generating an alternating magnetic field for inductive energy transmission to another energy coil of another inductive charging device in an energy transmission mode and/or for receiving energy transmitted inductively from the other energy coil in the energy transmission mode;
a positioning device with at least two positioning coils for generating positioning magnetic fields for detecting the relative positioning of the energy coils to each other in a positioning mode and/or for detecting the positioning magnetic fields generated by further positioning coils of a further positioning device of the further inductive charging device for detecting the relative positioning of the energy coils to each other in the positioning mode; and
a test unit for testing the integrity of the positioning coils by
excitation of a positioning coil and/or the energy coil with a test signal, and
evaluation of a measurement signal induced in at least one non-excited positioning coil and/or the energy coil and/or a phase shift between current and voltage in the excited positioning coil and/or in at least one non-excited positioning coil.

According to a further aspect of the present invention, a corresponding method for testing the integrity of positioning coils of the inductive charging device is provided.

According to another aspect of the present invention, a vehicle is provided with an inductive charging device of the present invention. The vehicle can be, for example, a car, bus, truck, robot, forklift, driverless transport vehicle, etc.

Preferred embodiments of the invention are defined in the dependent claims. It is understood that the claimed method has similar and/or identical preferred embodiments as the claimed inductive charging device, in particular as defined in the dependent claims and as disclosed herein.

For correct positioning, for example using DIPS, it is essential that the electromagnetic characteristics of the individual positioning coils are known and remain as constant as possible over the service life of the application. This is the only way to ensure that the function of this electromagnetic application is correctly interpreted by other electromagnetic applications communicating with this electromagnetic application, thereby avoiding malfunctions that could potentially pose a risk. Compliance with these defined electromagnetic characteristics of all positioning coils in an electromagnetic application is therefore important for error-free operation.

However, due to tolerances and/or changes over time during use, it is difficult or impossible to guarantee that these electromagnetic characteristics will remain within the required tolerances throughout the entire period of use. Compliance with these defined electromagnetic characteristics of all positioning coils is generally only checked at the time of manufacture/delivery and, if necessary, at the time of installation. For high-quality applications or high risk potential, further checks may be carried out within defined maintenance intervals. Nevertheless, it cannot be ruled out that the required electromagnetic characteristics may change impermissibly between individual functional phases, leading to spontaneous malfunctions that were not foreseeable.

Even though inductive charging devices, and in particular their positioning devices, are generally designed to be very robust against different environmental conditions during installation, local conditions that were not known at the time of manufacture of the inductive charging device can also have an influence on the magnetic fields generated (in particular magnetically asymmetrical environmental conditions such as a nearby manhole cover). This may result in a deviation from the factory settings.

The invention is based on the idea of providing an in-situ integrity check of the electromagnetic characteristics of the positioning coils of an application (VA, GA). This makes it possible to check the electromagnetic integrity of the positioning coils at shorter intervals (e.g., daily, hourly, etc.) or, ideally, before each function call, thereby ensuring their safe operation and guaranteeing the positioning function and accuracy over a longer period of time, ideally over the entire service life of the inductive charging device.

According to the invention, it is envisaged to excite the positioning coils, preferably individually, and/or the energy coil with a test signal and to evaluate the response to this. For this purpose, a measurement signal induced in at least one non-excited positioning coil and/or the energy coil is evaluated. Alternatively or additionally, a phase shift between current and voltage in the excited positioning coil and/or in at least one non-excited positioning coil can be evaluated. This provides information about the integrity of the respective excited coil, i.e., an excited positioning coil or the excited power coil.

The integrity test of a positioning coil is understood to mean that the electromagnetic properties or electromagnetic characteristics (transmission and/or reception characteristics) of a positioning coil are checked. This also provides information about the integrity of the positioning magnetic field generated or received by the tested positioning coil, as this depends not only on the tested coil itself, but also on the magnetic environment (e.g., a broken magnetic field flux guide element) and/or an evaluating coil itself. In other words, information should be obtained as to whether the generation or reception of the positioning magnetic fields still corresponds to the desired, originally intended quality or whether, for any reason (wear, damage, long service life, etc.), deviations occur that could impair the accuracy and functionality of the positioning, so that appropriate countermeasures can be taken.

The test unit intended for excitation and evaluation can be implemented as hardware and/or software, for example as a programmed processor, controller, or control device.

In a preferred embodiment, the testing unit is designed to repeatedly test the integrity of the positioning coils at regular or irregular intervals, in particular at the beginning and/or end of a positioning mode. This reliably ensures integrity.

In a further embodiment, the test unit is designed to excite the individual positioning coils separately, one after the other, or to excite several positioning coils simultaneously with different test signals. Simultaneous testing reduces the time required for testing; sequential testing may be more accurate due to less mutual interference between the excitation signals of multiple coils. Alternatively, only one coil (e.g., the energy coil) can be excited and the integrity determined via the reaction in all other coils.

In one configuration, all positioning coils belonging to the DIPS system can also be excited simultaneously with a single frequency and the response in the energy coil can be evaluated. This means that the integrity check can be performed solely by evaluating a single signal, with the disadvantage that no information can be obtained from the single signal to narrow down the cause of the electromagnetic deviation. Preferably, the excitation signal for all excited positioning coils should be as identical as possible, i.e., have the same phase and frequency.

The test unit is preferably designed in a further development to generate the test signal in the form of an alternating current signal, in particular with an excitation frequency that differs from a coil frequency for which the respective positioning coil is designed, or with the coil frequency. An excitation frequency that differs from the coil frequency enables clear detection that the positioning coil is not in positioning mode, but rather in test mode, so to speak.

The test unit can also be designed to simultaneously excite at least two positioning coils using identical test signals that are phase-shifted by 180° and to evaluate the measurement signals recorded by a non-excited positioning coil arranged symmetrically to the excited positioning coils. The reaction in the non-excited, also electromagnetically symmetrical positioning coil should be virtually eliminated to zero. Any deviation from this indicates an integrity problem.

Alternatively, one design provides for a single coil to perform an integrity check on itself. For this purpose, the phase shift between the (excitation) current and voltage signal can be evaluated, for example.

The test unit is preferably designed to evaluate current and/or voltage as a measurement signal in the non-excited positioning coil. To determine integrity by means of direct measurement, different signals can thus be evaluated, for example a measurement of the voltage in a non-actively excited coil, a measurement of the current in a non-actively excited coil, and/or a phase shift from current to voltage in an actively excited coil.

In a further development, the testing unit is designed to evaluate the recorded measurement signal by comparing it with an expected measurement signal from the excited positioning coils and/or by comparing the recorded measurement signals from different positioning coils. The strength of the excitation can be set, for example, so that the strength of the response is clearly above or clearly below normal electrical responses (e.g., signal strengths during a positioning process) and can thus be clearly detected as an integrity check. The comparison can provide information about the extent of the integrity problem.

In another embodiment, the inductive charging device further comprises an evaluation unit which is designed to perform one or more of the following measures if the integrity check of the positioning coils reveals that at least one positioning coil does not meet an integrity condition:
adjustment of the amplitude of an excitation current of the at least one positioning coil in positioning mode;
adjustment, addition, or removal of electronic components for generating and/or processing the excitation current;
adjustment of the duty cycle of the excitation current;
adjustment of the evaluation; and
output and/or transmission of information to a service device and/or the further charging device that the positioning mode is not possible or that the detection of the relative positioning of the energy coils to each other in the positioning mode must be adjusted.

Depending on the specific application and design of the charging equipment, different measures can therefore be planned or taken in response to an integrity check that identifies a problem with the integrity of one or more coils. The measure may also depend on the extent of the integrity problem identified.

In an exemplary application, it is envisaged that the positioning device has several transmitting coils, in particular four or five transmitting coils, as positioning coils for generating a positioning magnetic field as an alternating magnetic field with different transmitting coil frequencies, in particular four transmitting coils, which are arranged symmetrically in a common plane. The positioning device can thus be designed, for example, as a position transmitting device and feature a coil arrangement with transmitting coils as in the known DIPS system. Furthermore, the inductive charging device can be designed as a stationary inductive charging device for installation on and/or in a ground surface.

In another exemplary application, it is envisaged that the positioning device has several receiving coils, in particular two or three receiving coils, as positioning coils for detecting the positioning magnetic field generated by the positioning device of the further inductive charging device, wherein the receiving coils are arranged crosswise to each other. The positioning device can thus be designed, for example, as a position receiving device and feature a coil arrangement with receiving coils as in the known DIPS system. Furthermore, the inductive charging device can be designed as a mobile inductive charging device for attachment to and/or in the underbody of a vehicle.

The present invention can thus be used in conjunction with a DIPS system in both GA and VA to check and ensure the integrity of the individual coils.

It is understood that the features mentioned above and those to be explained below may be used not only in the combination indicated in each case, but also in other combinations or on their own, without departing from the scope of the present invention.

### BRIEF DESCRIPTION OF THE DRAWINGS

Exemplary embodiments of the invention are shown in the following drawings and are explained in more detail in the following description, wherein identical reference numerals refer to identical or similar or functionally identical components. The following is shown in the figures below:

FIG. 1 shows a highly simplified representation of a vehicle with an inductive charging device according to the invention;

FIG. 2 shows a top view of an inductive charging device according to the invention with a close-range position transmitting device and a remote positioning transmitting device;

FIG. 3 shows an inductive charging device with a position receiving device for a vehicle charging system according to the invention; and

FIG. 4 shows a block diagram of a charging system according to the invention.

### DETAILED DESCRIPTION

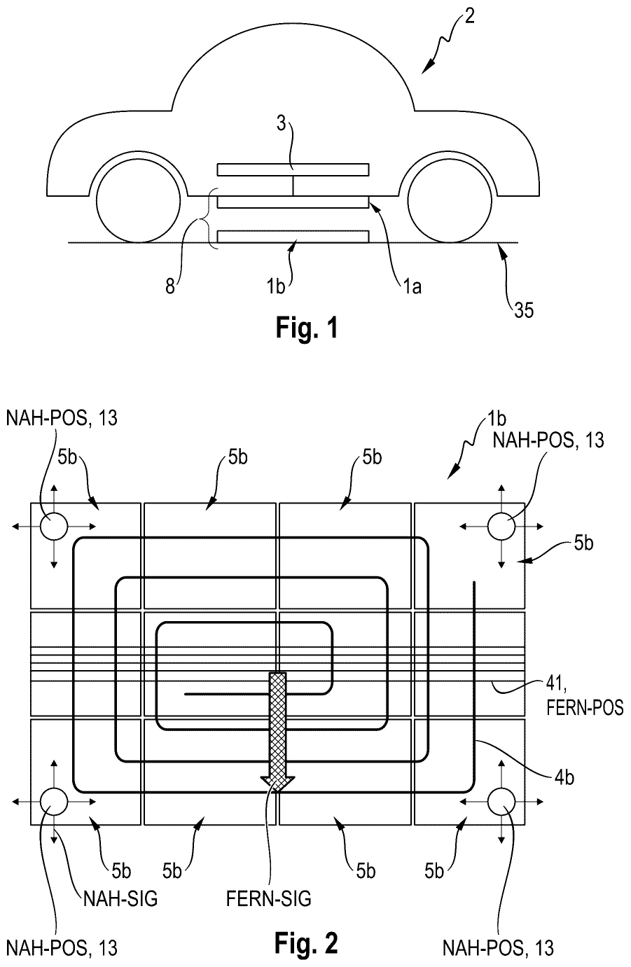

FIG. 1 shows an example of a mobile inductive charging device 1a, which is arranged on a vehicle 2 with an energy storage device 3 and is positioned above a stationary inductive charging device 1b. During operation, energy can be transmitted from the stationary inductive charging device 1b to the mobile inductive charging device 1a and the vehicle's energy storage device 3 can be charged as a result.

The mobile inductive charging device 1a and the stationary inductive charging device 1b together form or are part of a vehicle charging system 8. In principle, it is also possible to operate the vehicle charging system 8 bidirectionally. In the process, energy can be temporarily transmitted from the mobile inductive charging device 1a to the stationary inductive charging device 1b. The stationary inductive charging device 1b arranged on the substrate 35 in FIG. 1 can alternatively also be recessed into the roadway (not shown here). In a recessed arrangement, the inductive charging device 1b can be covered by certain layers of the road surface or be flush with the road surface. The mobile inductive charging device 1a is mounted, for example, in or on the underbody of the vehicle 2. Both inductive charging devices 1a, 1b each have an energy transmission winding (energy coil) and preferably several flux guide elements.

FIG. 2 shows a top view of an embodiment of an inductive charging device 1b. In this example, it features a positioning device (also referred to as a position transmitting device) with a close-range position transmitting device CLOSE-POS and a remote position transmitting device REMOTE-POS, as implemented, for example, in a DIPS system known from the SAE standard, among others. The close-range position transmitting device CLOSE-POS is implemented here in the form of four close-range transmitting windings 13 (transmitting coils; also generally referred to as positioning coils) designed as flat coils, but can also be implemented with more or fewer transmitting windings. The remote position transmitting device REMOTE-POS is implemented here as a solenoid (positioning signal winding), but can also be omitted if necessary. During a positioning process, the remote position transmitting device REMOTE-POS transmits a remote positioning signal REMOTE-SIG in the form of an alternating magnetic field (also referred to as a remote positioning magnetic field). During a positioning process, the close-range position transmitting device CLOSE-POS transmits several close-range positioning signals CLOSE-SIG in the form of alternating magnetic fields (also referred to as close-range positioning magnetic fields), which differ from each other and from the remote positioning signal REMOTE-SIG in terms of frequency, for example. Furthermore, an energy transmission winding 4b (energy coil), preferably designed as a flat coil, and flux guide elements 5b, for example in the form of ferrite plates, are provided.

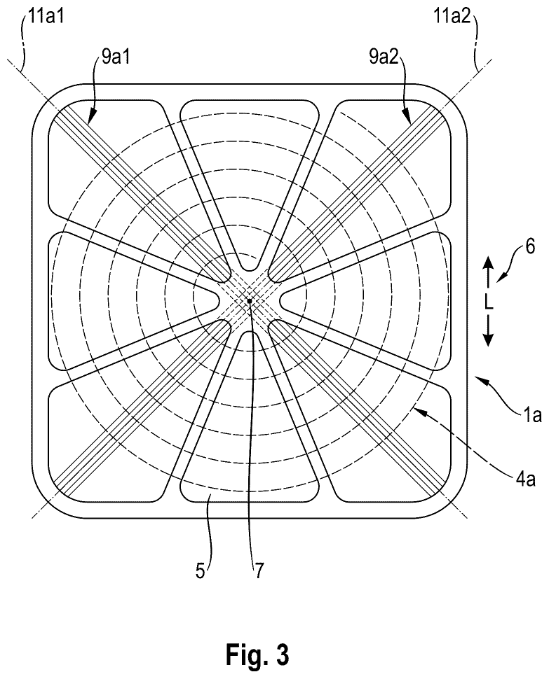

FIG. 3 shows a mobile inductive charging device 1a, which has a positioning device (also referred to as a position receiving device) with two sensor windings 9a1 and 9a2 (receiving coils; also generally referred to as positioning coils), as implemented, for example in a DIPS system known from the SAE standard, among others. In principle, only one sensor winding or multiple sensor windings can be used. In the present exemplary embodiment, eight flux guide elements 5a are shown, which are arranged radially around the center 7 of the energy transmission winding 4a in the plane. However, there may also be more or fewer flux guide elements. The energy transmission winding 4a, preferably designed as a flat coil, which is concealed in the top view by the flux guide elements 5a, is indicated by a dashed line. The sensor windings 9a1, 9a2 are designed here as solenoids (also known as cylinder coils).

In this example, the first sensor winding 9a1 is arranged axially symmetrical to the second sensor winding 9a2 with respect to the longitudinal direction 6 of the vehicle. The first sensor winding 9a1 and the second sensor winding 9a2 intersect at least approximately in the center 7 of the energy transmission coil 4a. The first sensor winding 9a1 has a first radial longitudinal direction 11a1 and the second sensor winding 9a2 has a second radial longitudinal direction 11a2. The angle between the first radial longitudinal direction 11a1 and the vehicle longitudinal direction 6 is at least approximately equal to the angle between the second radial longitudinal direction 11a2 and the vehicle longitudinal direction 6; however, the angles may also be different. The sensor windings 9a1, 9a2 thus form a cross-shaped arrangement.

During the charging process, the vehicle 2 is positioned above the stationary inductive charging device 1b and energy is transmitted to the inductive charging device 1a. The flux guide elements perform the function of flux guidance. When they are charged, the field lines of the magnetic field run approximately in a radial direction in them. Since the first radial longitudinal direction 11a1 and the second radial longitudinal direction 11a2 are also aligned radially and thus at least approximately parallel to the magnetic field lines, relatively little to no voltage is induced in the first sensor winding 9a1 and in the second sensor winding 9a2. This is advantageous because the high power levels of energy transmission and the resulting high current densities could otherwise easily destroy the sensor windings. Additional effort to prevent the destruction of the arrangement is therefore not necessary.

The inductive charging device 1b and the inductive charging device 1a can be part of a vehicle charging system 8 according to the invention. In this case, the position receiving device can receive signals from both the close-range position transmitting device CLOSE-POS and the remote position transmitting device REMOTE-POS. This is advantageous because a position receiving device can be used to operate two different positioning methods that function optimally at two different distance ranges. Further details on the basic design and functionality of the inductive charging devices 1a, 1b can be found in the documents mentioned at the beginning, to which explicit reference is made here.

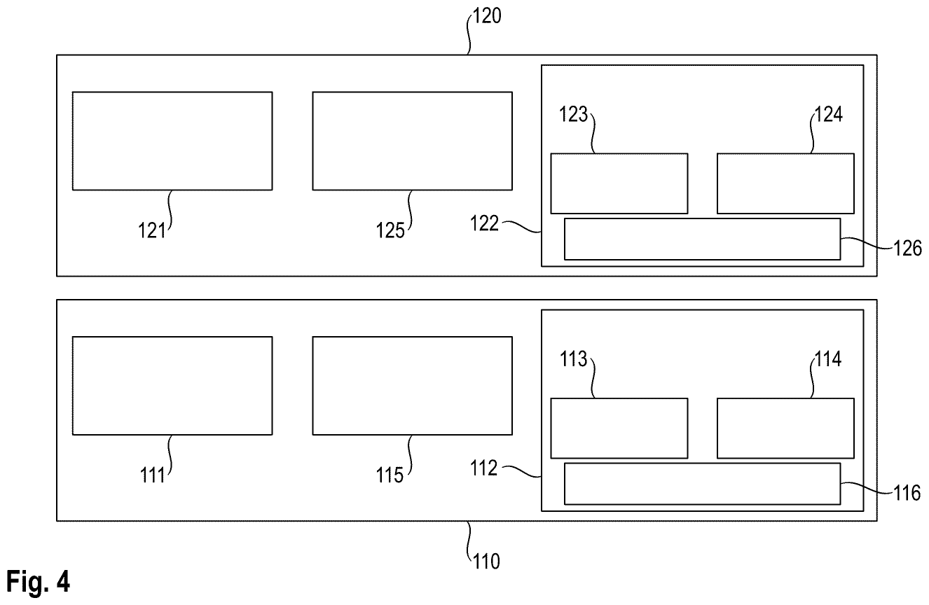

FIG. 4 shows a block diagram of an embodiment of a charging system 100 according to the invention for inductive energy transmission with a first charging device 110 and a second charging device 120.

The first charging device 110 comprises a first charging unit (energy coil) 111 for inductively transmitting energy to a second charging unit 121 of the second charging device 120 in an energy transmission mode. It also comprises a position transmitting device 112 with at least two transmitting coils 113, 114, each with a coil winding for generating positioning magnetic fields, and a test unit 115 for testing the integrity of the transmitting coils 113, 114. An optional control unit 116 is also provided for controlling the transmitting coils 113, 114.

The second charging device 120 comprises the second charging unit (energy coil) 121 for inductively transmitting energy from the first charging unit 111 in energy transmission mode. It also comprises a position receiving device 122 with at least two magnetic field detection units (receiving coils) 123, 124 for detecting a positioning magnetic field generated by the position transmitting device 112 of the first charging device 110, a testing unit 125 for testing the integrity of the receiving coils 123, 124, and an evaluation unit 126 for evaluating the detected positioning magnetic fields to detect the positioning of the second charging device 120 relative to the first charging device 110.

The first charging unit 111 can be designed as an inductive (preferably stationary) charging unit, for example like the energy coil 4b shown in FIG. 2. The second charging unit 121 is designed accordingly as an inductive (preferably mobile) charging unit, for example like the energy coil 4a shown in FIG. 3.

According to the invention, the test unit 115 is designed to excite a transmitting coil (for example, transmitting coil 113) and/or the first energy coil 111 with a test signal and to evaluate a test signal induced in at least one non-excited transmitting coil (in the example, the transmitting coil 114) and/or the energy coil 111 and/or a phase shift between current and voltage in the excited transmitting coil (in the example, the transmitting coil 113) and/or in at least one non-excited transmitting coil (in the example, the transmitting coil 114).

Similarly, the test unit 125 is designed to excite a receiving coil (for example, the receiving coil 123) and/or the second energy coil 121 with a test signal, and for evaluating a measurement signal induced in at least one non-excited receiving coil (in the example, receiving coil 124) and/or a phase shift between current and voltage in the excited receiving coil (in the example, receiving coil 123) and/or in at least one non-excited receiving coil (in the example, the receiving coil 124).

The energy coil (and also ferrites preferred for magnetic flux guidance) is preferably symmetrical in design. According to the requirements for ClosePos coils (transmitting coils) in SAE standard J2954, the geometry of the four transmitting coils in the DIPS positioning system should be very similar (preferably identical) and the arrangement (distribution) should be very symmetrical (see, for example, FIG. 2). Due to these conditions, the coupling factors between the individual ClosePos coils and the energy coil are therefore very similar or even identical, provided that the integrity of the system is ensured. This property can be used to detect the integrity of the system, especially the coils.

According to a preferred implementation, two ClosePos coils (transmitting coils) are selected, into which a current with the same frequency and amplitude but in reverse phase is fed, for example via their driver circuits. The induced current generated in the energy coil is observed. A sufficiently small induced current (which cannot be completely eliminated due to system tolerances) can be considered the basis for the integrity of the two selected transmitting coils. This test method can then be repeated for all ClosePos coils (transmitting coils) to verify system integrity.

In another configuration, measurements are taken in which several signals overlap without canceling each other out, resulting in a measurement signal with an evaluable amplitude.

For charging devices with three or more coils, integrity can also be determined by exciting multiple coils with signals of the same frequency and evaluating a superimposed signal. In an advantageous solution, two coils with electromagnetically symmetrical properties are excited at the same frequency but with opposite phases, wherein the reaction in a third coil, which is also electromagnetically symmetrical, should be virtually zero. The response can be evaluated in the form of a current and/or voltage signal.

It should be noted that, in the context of the present invention, the term “signal” should be understood to mean that the signals considered for evaluation have an identical frequency. However, this does not rule out the possibility that other signals with different frequencies may also exist at the same time. Thus, each integrity check described here always applies on the basis of a single test frequency, which may be filtered out of a total signal using Fourier transformation.

The duration of such an integrity check is less than 0.1 s at excitation frequencies >10 kHz, as a magnetically stationary state is already reached after a few thousand oscillations. In terms of the overall positioning time scale, this time frame is therefore negligible.

The response can be checked, for example, using appropriately calibrated passive electronic circuits (resistor, diode, capacitor) alone, so that no switching components are required. Similarly, the status can be maintained for a specific period of time (e.g., 1 minute) using a corresponding capacitor in order to activate the enable signal for the entire positioning process if possible.

Furthermore, an oscillating circuit may be provided in the measuring electronics (the test unit) for evaluating the electromagnetic response, the resonance frequency of which is set to the test frequency in the existing electromagnetic system. This increases the strength (amplitude) of the electromagnetic response, which has a positive effect on sensitivity when detecting possible deviations. However, simple designs are also conceivable without an oscillating circuit.

If the situation at the installation site changes the electromagnetic characteristics of the coils, this can be detected and, if necessary, taken into account in the test unit or the corresponding control unit of the transmitting coil or the evaluation unit of the receiving coils. For example, attempts can be made to adjust the charging system or individual components thereof to local conditions so that standard conformity and thus positioning accuracy can be restored or improved.

The adjustment can be made, for example, by changing the amplitude of the current excitation, variable and/or switchable components (resistors, capacitors), adjusting the duty cycle of the control electronics (e.g., in the inverter of the control unit), etc.

Generally known measurement principles for current and voltage in electromagnetically coupled inductive systems can also be used to determine verifiable measurement signals.

The present invention thus offers a number of advantages. The electromagnetic integrity of the charging equipment can be guaranteed virtually permanently. Malfunctions during the positioning process due to changes in electromagnetic environmental conditions can be almost completely ruled out, which significantly increases the safety and reliability of positioning and ensures consistent performance. Furthermore, improved functional safety is ensured, with virtually no impact on the process flow. The effort required for implementation and application in terms of time, space, and costs is minimal. Finally, implementation does not result in any downtime for the charging system.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both elements, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the phrase “at least one of” followed by successive elements separate by the word “and” (e.g., “at least one of A and B”) is to be interpreted the same as “and/or” and as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

All matter contained in the above description or shown in the accompanying drawings shall be interpreted as illustrative only and not limiting. Changes in detail or structure may be made without departing from the present disclosure.

1. An inductive charging device, comprising:
an energy coil configured to provide an alternating magnetic field for inductive energy transmission to a second energy coil of a second inductive charging device in an energy transmission mode and/or to receive energy transmitted inductively from the second energy coil in the energy transmission mode;
a positioning mechanism including at least two positioning coils configured to provide a plurality of positioning magnetic fields for detecting a relative positioning of the energy coil and the second energy coil to each other in a positioning mode and/or to detect a plurality of second positioning magnetic fields provided by at least two second positioning coils of a second positioning mechanism of the second inductive charging device for detecting the relative positioning of the energy coil and the second energy coil to each other in the positioning mode; and
a testing unit configured to test an integrity of the at least two positioning coils via:
excitation of at least one positioning coil of the at least two positioning coils and/or the energy coil with a test signal; and
evaluation of i) a measurement signal induced in at least one non-excited positioning coil of the at least two positioning coils and/or the energy coil and/or ii) a phase shift between current and voltage in the at least one excited positioning coil and/or in at least one non-excited positioning coil of the at least two positioning coils.

2. The inductive charging device according to claim 1, wherein the testing unit is further configured to repeatedly test the integrity of the at least two positioning coils at regular intervals.

3. The inductive charging device according to claim 1, wherein the test unit is further configured for separate, sequential excitation of individual positioning coils of the at least two positioning coils and/or for simultaneous excitation of several positioning coils of the at least two positioning coils with a plurality of different test signals.

4. The inductive charging device according to claim 1, wherein the test unit is further configured to provide the test signal as an alternating current signal.

5. The inductive charging device according to claim 1, wherein:
the at least two positioning coils includes a plurality of positioning coils; and
the test unit is configured for i) simultaneous excitation of at least two of the plurality of positioning coils via identical test signals that are phase-shifted by 180° and ii) evaluation of a plurality of measurement signals detected via a non-excited positioning coil of the plurality of coils that is arranged symmetrically to the at least two excited positioning coils.

6. The inductive charging device according to claim 1, wherein the testing unit is configured to evaluate current and/or voltage as the measurement signal in the at least one non-excited positioning coil.

7. The inductive charging device according to claim 1, wherein the testing unit is configured to evaluate the measurement signal via i) comparing the measurement signal with an expected measurement signal from the at least one excited positioning coil and/or ii) comparing a plurality of measurement signals from different positioning coils of the at least two positioning coils.

8. The inductive charging device according to claim 1, further comprising an evaluation unit, wherein, if an integrity check of the at least two positioning coils reveals that at least one positioning coil of the at least two positioning coils does not meet an integrity condition, the evaluation unit is configured to:
adjust an amplitude of an excitation current of at least one positioning coil of the at least two positioning coils in the positioning mode;
adjust, add, and/or remove one or more of a plurality of electronic components for generating and/or processing the excitation current;
adjust a duty cycle of the excitation current;
adjust the evaluation; and/or
output and/or transmit information to a service device and/or the second inductive charging device that the positioning mode is not possible and/or that detection of the relative positioning of the energy coil and the second energy coil to each other in the positioning mode must be adjusted.

9. The inductive charging device according to claim 1, wherein the positioning mechanism includes a plurality of transmitting coils as the at least two positioning coils for providing a respective positioning magnetic field as an alternating magnetic field with a respective different transmitting coil frequency, which are arranged symmetrically distributed in a common plane.

10. The inductive charging device according to claim 1, wherein the inductive charging device is a stationary inductive charging device for attachment to and/or in a ground surface.

11. The inductive charging device according to claim 1, wherein the positioning includes a plurality of receiving coils as the at least two positioning coils for detecting the plurality of second positioning magnetic fields provided by the second positioning mechanism of the second inductive charging device, and wherein the plurality of receiving coils are arranged crossed to each other.

12. The inductive charging device according to claim 11, wherein the inductive charging device is a mobile inductive charging device for attachment to and/or in a vehicle underbody.

13. A vehicle, comprising an inductive charging device according to claim 1.

14. A method for testing the integrity of a plurality of positioning coils of an inductive charging device including an energy coil configured to provide an alternating magnetic field for inductive energy transmission to a second energy coil of a second inductive charging device in an energy transmission mode and/or to receive energy transmitted inductively from the second energy coil in the energy transmission mode, and a positioning mechanism including at least two positioning coils configured to provide a plurality of positioning magnetic fields for detecting a relative positioning of the energy coil and the second energy coil to each other in a positioning mode and/or detect a plurality of second positioning magnetic fields provided by at least two second positioning coils of a second positioning mechanism of the second inductive charging device for detecting the relative positioning of the energy coil and the second energy coil to each other in the positioning mode, the method comprising:
exciting a positioning coil of the at least two positioning coils and/or the energy coil with a test signal; and
evaluating i) a measurement signal induced in at least one non-excited positioning coil of the at least two positioning coils and/or the energy coil and/or ii) a phase shift between current and voltage in the excited positioning coil and/or in at least one non-excited positioning coil of the at least two positioning coils.

15. The method according to claim 14, wherein evaluating the measurement signal includes:
comparing the measurement signal with an expected measurement signal from the at least one excited positioning coil; and/or
comparing a plurality of measurement signals from different positioning coils of the at least two positioning coils.

16. The inductive charging device according to claim 1, wherein the testing unit is further configured to repeatedly test the integrity of the at least two positioning coils at irregular intervals.

17. The inductive charging device according to claim 1, wherein the testing unit is further configured to repeatedly test the integrity of the at least two positioning coils at regular and/or irregular intervals at a beginning of the positioning mode.

18. The inductive charging device according to claim 1, wherein the testing unit is further configured to repeatedly test the integrity of the at least two positioning coils at regular and/or irregular intervals at an end of the positioning mode.

19. The inductive charging device according to claim 1, wherein the test unit is further configured to provide the test signal as an alternating current signal with an excitation frequency that differs from a respective coil frequency of the at least one positioning coil.

20. The inductive charging device according to claim 1, wherein the test unit is further configured to provide the test signal as an alternating current signal with an excitation frequency that corresponds to a respective coil frequency of the at least one positioning coil.
